(19) United States
(12) Patent Application Publication
(10) Pub. No.: US 2024/0355848 A1
(43) Pub. Date: Oct. 24, 2024

(54) IMAGE SENSOR AND METHOD OF MANUFACTURING THE SAME

(71) Applicant: Samsung Electronics Co., Ltd., Suwon-si (KR)

(72) Inventors: Jinsu PARK, Suwon-si (KR); Nosan PARK, Suwon-si (KR); Jae-Kwan SEO, Suwon-si (KR); Wonchun YANG, Suwon-si (KR); Kookki LEE, Suwon-si (KR); Seul-Young JEONG, Suwon-si (KR)

(73) Assignee: Samsung Electronics Co., Ltd., Suwon-si (KR)

(21) Appl. No.: 18/490,177

(22) Filed: Oct. 19, 2023

(30) Foreign Application Priority Data
Apr. 24, 2023 (KR) 10-2023-0053605

(51) Int. Cl. H01L 27/146; H04N 25/13

(52) U.S. Cl. CPC H01L 27/14621; H01L 27/14627; H01L 27/14645; H01L 27/14685; H04N 25/135

(57) ABSTRACT

A manufacturing method of an image sensor includes inputting a substrate in an equipment, wherein a sensor array and a plurality of pads are on the substrate; forming a plurality of vortex generating patterns at regular intervals between the plurality of pads and the sensor array; and coating a photo resist while rotating the substrate based on operating the equipment.

### CROSS-REFERENCE TO RELATED APPLICATIONS

This application claims priority under 35 U.S.C. § 119 to Korean Patent Application No. 10-2023-0053605 filed on Apr. 24, 2023, in the Korean Intellectual Property Office, the disclosures of which are incorporated by reference herein in their entireties.

### BACKGROUND

Example embodiments of the present inventive concepts described herein relate to image sensors, and more particularly, relate to image sensors and methods of manufacturing the same.

The image sensor is a semiconductor device changing an optical image into an electrical signal. The image sensor may be classified into a charge coupled device (CCD) and a complementary metal-oxide semiconductor (CMOS) image sensor. The CCD is a device in which individual MOS capacitors are located very close to each other and charge carriers are stored and transported in each of the MOS capacitors. In addition, the CMOS image sensor is a device which uses a CMOS technology using a control circuit and a signal processing circuit as peripheral circuits to make MOS transistors as many as the number of pixels and uses a switching method detecting outputs in turn using the MOS transistors.

The CMOS image sensor may generally comprise an active pixel sensor (APS) array area that detects light and generates an electrical signal, and a logic area (or a peripheral circuit area) that processes an electrical signal generated in the APS array area. The APS array area may include a photoelectric conversion unit that detects light and converts it into the electrical signal. As the area of the photoelectric conversion unit (for example, photo diode) increases, photo sensitivity of the image sensor becomes better.

The CMOS image sensor may be produced using a semiconductor manufacturing process. A color filter of the CMOS image sensor is created by coating a photo resist through the semiconductor manufacturing process, and stains may occur in a process of creating the color filter. In the case of a low-pixel CMOS image sensor, stains of a color filter may not be a big problem. However, as a high-pixel CMOS image sensor are increasingly required, stains of a color filter may affect a performance of the CMOS image sensor.

### SUMMARY

Some example embodiments of the present inventive concepts provide an image sensor having reduced, minimum, or no stains on a color filter because a photo resist is uniformly coated by disposing a vortex generating pattern evenly spaced between a sensor array area and a pad area and a manufacturing method of the image sensor.

According to some example embodiments, a manufacturing method of an image sensor may include: inputting a substrate in an equipment, wherein a sensor array and a plurality of pads are on the substrate; forming a plurality of vortex generating patterns at regular intervals between the plurality of pads and the sensor array; and coating a photo resist while rotating the substrate based on operating the equipment.

According to some example embodiments, a manufacturing method of an image sensor may include: inputting a substrate in an equipment, wherein a sensor array and a plurality of pads are on the substrate and a plurality of lines are connected to the sensor array on the substrate; filling a cavity of a vertical via connecting the plurality of pads and a plurality of lines connected to the sensor array; forming a plurality of vortex generating patterns at regular intervals between the plurality of pads and the sensor array; coating a photo resist while rotating the substrate based on operating the equipment; forming color filters on the sensor array; and forming a lens portion on the sensor array.

According to some example embodiments, an image sensor includes: a sensor array including a two-dimensional arrangement of a plurality of unit pixels; a plurality of pads surrounding the sensor array at irregular intervals; and a plurality of vortex generating patterns arranged at regular intervals between the plurality of pads and the sensor array. The regular intervals may be equal to a minimum interval of the irregular intervals between the plurality of pads.

### BRIEF DESCRIPTION OF THE DRAWINGS

The above and other objects and features of the present inventive concepts will become apparent by describing in detail some example embodiments thereof with reference to the accompanying drawings.

FIG. 1 is a block diagram illustrating an image sensor according to some example embodiments.

FIG. 2 is a diagram illustrating a plurality of unit pixels included in a sensor array of FIG. 1 according to some example embodiments.

FIG. 3 is a diagram illustrating one unit pixel of FIG. 2 as an example according to some example embodiments.

FIG. 4 is a diagram illustrating an example of causing stains in a sensor array during manufacturing of the image sensor of FIG. 1 according to some example embodiments.

FIG. 5 is a diagram illustrating another example of causing stains in a sensor array during manufacturing of the image sensor of FIG. 1 according to some example embodiments.

FIG. 6 is a diagram illustrating an image sensor including a vortex generating pattern to minimize staining during photo resist coating according to some example embodiments.

FIG. 7 is a cross-sectional view illustrating along a line B-B′ of FIG. 6 according to some example embodiments.

FIG. 8 is a diagram illustrating an effect according to an arrangement of the vortex generating pattern of FIG. 6 according to some example embodiments.

FIG. 9 is a flowchart illustrating an example of a method of manufacturing an image sensor including the vortex generating pattern of FIG. 6 according to some example embodiments.

FIG. 10 is a flowchart illustrating another example of a method of manufacturing an image sensor including the vortex generating pattern of FIG. 6 according to some example embodiments.

FIGS. 11, 12, 13, 14, 15, 16, and 17 are cross-sectional views illustrating each of steps of manufacturing an image sensor according to some example embodiments.

### DETAILED DESCRIPTION

Below, some example embodiments of the present inventive concepts will be described in detail and clearly to such an extent that an ordinary one in the art easily implements the inventive concepts.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

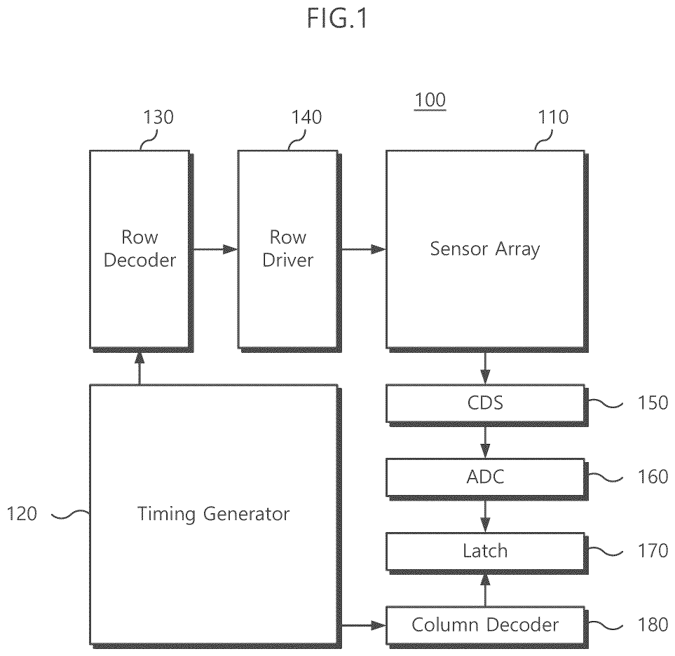

FIG. 1 is a block diagram illustrating an image sensor according to some example embodiments. Referring to FIG. 1, an image sensor 100 may include a sensor array 110 (for example, an active pixel sensor (APS)), a timing generator 120, a row decoder 130, a row driver 140, a correlated double sampler 150, an analog-to-digital converter 160, a latch unit 170, and a column decoder 180.

According to some example embodiments, the sensor array 110 may include a plurality of unit pixels arranged two-dimensionally (e.g., a two-dimensional array of a plurality of unit pixels, a two-dimensional arrangement of a plurality of unit pixels, etc.). For example, the plurality of unit pixels may perform a function of converting an optical image into an electrical output signal. The sensor array 110 may be driven by receiving a plurality of driving signals such as a row selection signal, a reset signal, and a charge transfer signal from the row driver 140. Electrical output signals converted through the plurality of unit pixels may be provided to the correlated double sampler 150 through vertical signal lines.

According to some example embodiments, the timing generator 120 may provide a timing signal and a control signal to the row decoder 130 and the column decoder 180. For example, the timing generator 120 may include a logic control circuit, a phase lock loop (PLL) circuit, a timing control circuit, or a communication interface circuit.

According to some example embodiments, the row decoder 130 may provide a driving signal for each row of a plurality of unit pixels. The row driver 140 may provide a plurality of driving signals for driving the plurality of unit pixels to the sensor array 110 according to a result decoded by the row decoder 130. As an example, when the plurality of unit pixels are arranged in a matrix form, each of the plurality of driving signals may be provided for each row.

According to some example embodiments, the correlated double sampler 150 may receive, hold, and sample an output signal formed by the sensor array 110 through a vertical signal line. For example, the correlated double sampler 150 may doubly sample a specific noise level and a signal level by an output signal, and output a difference level corresponding to a difference between the specific noise level and the signal level.

According to some example embodiments, the analog-to-digital converter 160 may convert an analog signal corresponding to the difference level into a digital signal and output the converted digital signal. The latch unit 170 may latch the digital signal, and the latched signal may be sequentially output to an image signal processing unit (not shown) according to a decoding result of the column decoder 180.

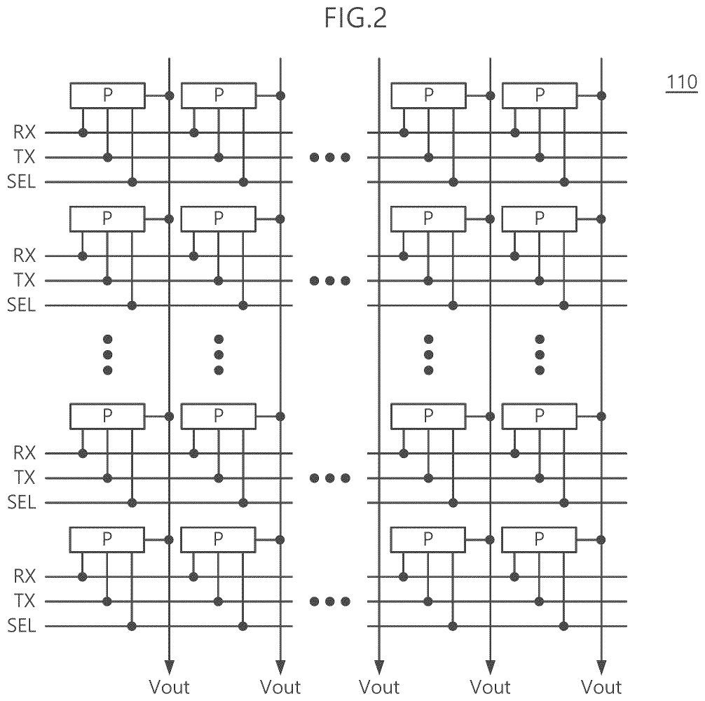

FIG. 2 is a diagram illustrating a plurality of unit pixels included in a sensor array of FIG. 1 according to some example embodiments. Referring to FIGS. 1 and 2, the sensor array 110 may include a plurality of unit pixels P arranged two-dimensionally (e.g., a two-dimensional array of a plurality of unit pixels P). The sensor array 110 may receive a row selection signal SEL, a reset signal RX, and a charge transfer signal TX from the row driver 140.

According to some example embodiments, each unit pixel P may generate an electrical signal based on incident light. For example, each unit pixel P may be driven by a charge transfer signal TX, a reset signal RX, and a row selection signal SEL. The electrical output signal Vout converted in each unit pixel P may be provided to the correlated double sampler 150 through a vertical signal line.

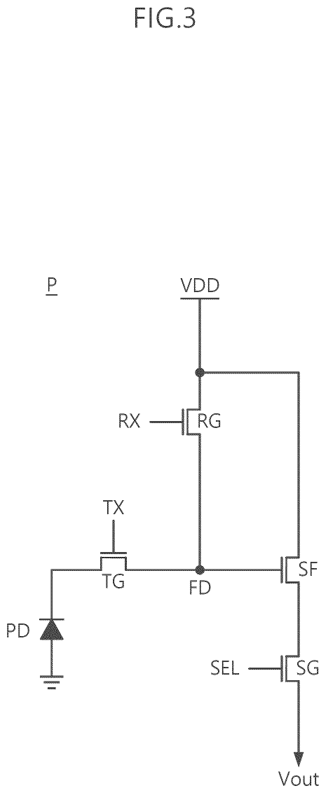

FIG. 3 is a diagram illustrating one unit pixel of FIG. 2 as an example according to some example embodiments. Referring to FIGS. 1 to 3, a unit pixel P may include a light receiving element PD, a transfer transistor TG, a floating diffusion region FD, a reset transistor RG, and a source follower transistor SF. and a selection transistor SG.

According to some example embodiments, the light receiving element PD may generate and accumulate charges in proportion to an amount of incident light from an outside. For example, the light receiving element PD may be connected to the transfer transistor TG transferring accumulated charges to the floating diffusion region FD. As an example, the light receiving element PD may include a photo diode, a photo transistor, a photo gate, a pinned photo diode (PPD), or any combination thereof.

According to some example embodiments, the transfer transistor TG may transfer charges generated from the light receiving element PD to the floating diffusion region FD according to a transfer signal TX. For example, one end of the transfer transistor TG may be connected to the light receiving element PD, and the other end of the transfer transistor TG may be connected to the floating diffusion region FD. The transfer transistor TG may be driven by the transfer signal TX.

According to some example embodiments, the floating diffusion region FD is a region in which charge is converted into voltage. For example, since the floating diffusion region FD has a parasitic capacitance, charges may be accumulated. Furthermore, the floating diffusion region FD may be electrically connected to a gate of the source follower transistor SF to control the source follower transistor SF.

According to some example embodiments, the source follower transistor SF may amplify a change in electrical potential of the floating diffusion region FD receiving charge from the light receiving element PD to output an output signal Vout. For example, the source follower transistor SF may serve as a source follower buffer amplifier in combination with a constant current source (not shown) positioned outside the plurality of unit pixels P. When the source follower transistor SF is turned on, a specified electrical potential (for example, power supply voltage VDD) provided to a drain of the source follower transistor SF may be transferred to a drain of the selection transistor SG.

According to some example embodiments, the selection transistor SG may select unit pixels P to be read in a unit row. For example, the selection transistor SG may be driven by a row selection signal SEL. When the selection transistor SG is turned on, the specified electrical potential (for example, power supply voltage VDD) provided to the drain of the source follower transistor SF may be output as the output signal Vout.

According to some example embodiments, the reset transistor RG may periodically reset the floating diffusion region FD. For example, the reset transistor RG may be driven by a reset signal RX. When the reset transistor RG is turned on by the reset signal RX, the specified electrical potential (for example, power supply voltage VDD) provided to a drain of the reset transistor RG may be transferred to the floating diffusion region FD.

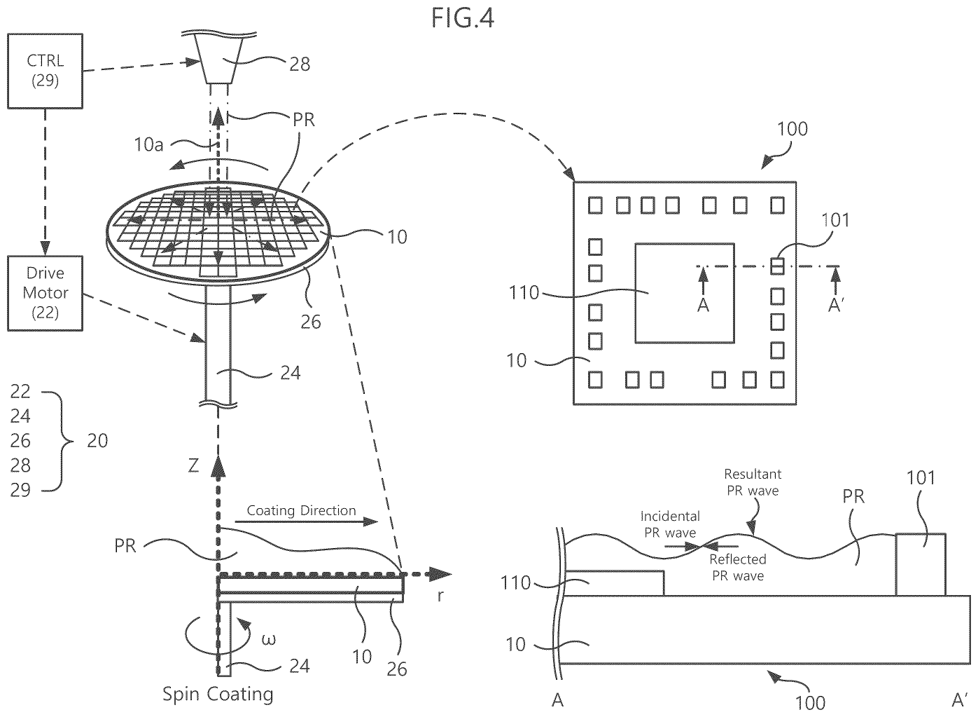

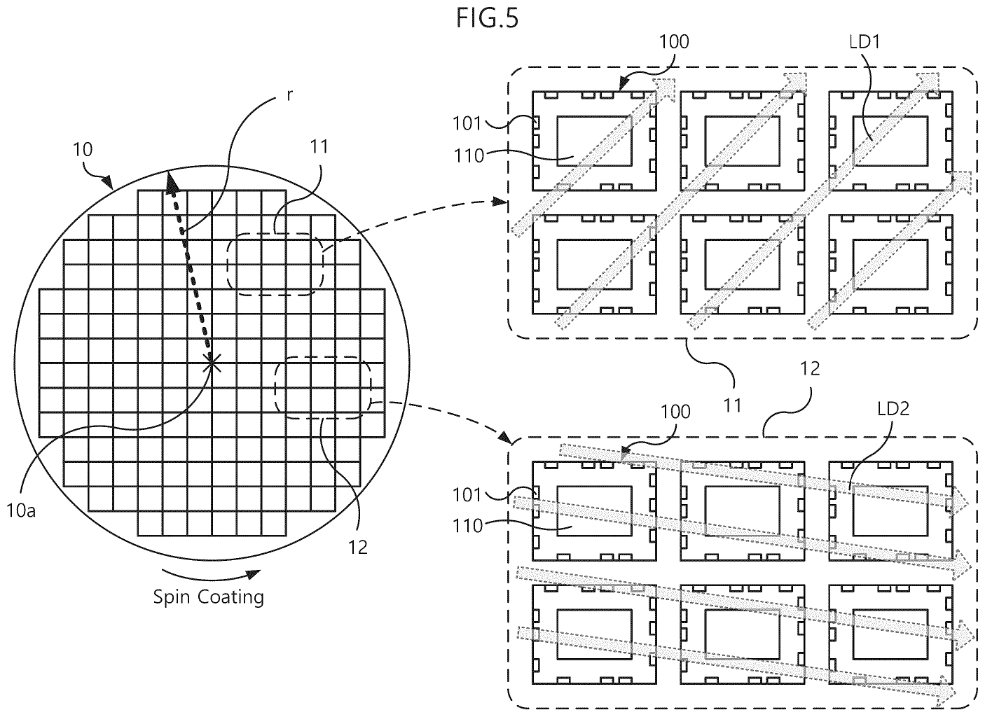

FIG. 4 is a diagram illustrating an example of causing stains in a sensor array during manufacturing of the image sensor of FIG. 1 according to some example embodiments. FIG. 5 is a diagram illustrating another example of causing stains in a sensor array during manufacturing of the image sensor of FIG. 1 according to some example embodiments. Referring to FIGS. 4 and 5, the image sensor 100 may be formed on a substrate 10 (for example, a wafer substrate). When the image sensor 100 is manufactured, a plurality of image sensors 100 may be formed together on the substrate 10. When a color filter is created in the sensor array 110, a photo resist PR may be coated on the substrate 10 to create the color filter. At this time, the substrate 10 may rotate around the Z axis, and the photo resist PR may flow and spread out from a center (for example, Z axis) of the substrate 10 to an outside (e.g., moving in a radial direction “r”). The photo resist PR may include, for example, polymethylmethacrylate (PMMA), Phenolic Novolac Resin, a mixture of Bisphenol A Novolac epoxy, an organic solvent such as gamma-butyrolactone GBL or cyclopentanone, and Triarylsulfonium/hexafluoroantimonate salt (the mixture referred to as SU-8), or the like. A photo resist PR may include a colorant, color dye, color pigment, or the like which may configure the coated photo resist PR to form a color filter configured to color a particular wavelength spectrum (e.g., a color of light corresponding to the color due, color pigment, colorant, or the like).

The coating of the photo resist PR may be implemented based on inputting the substrate 10 into an equipment, for example a spinning equipment 20 (also referred to herein as a spin coater, a spinner, or the like), and rotating the substrate 10 around the central axis 10a (which may be the central axis of the substrate 10) at a high rotational speed (e.g., 20 to 80 revolutions per second for 30 to 60 seconds) while applying a photo resist PR on the substrate 10 (e.g., at the central axis 10a) to cause the photo resist PR to move in radial direction “r” radially away from the central axis 10a to an outer edge of the substrate 10, based on “centrifugal force” induced by the rotation of the substrate 10. As shown, the spinning equipment 20 may include a turntable 26 upon which the inputted substrate 10 is supported, a drive shaft 24 connected to the turntable 10, a drive motor 22 (e.g., an electric motor, a servomotor, etc.) mechanically coupled to the turntable 26 via the drive shaft 24 and thus configured to cause the turntable 26 to rotate around central axis 10a based on operation of the drive motor 22, and a photo resist dispenser 28 configured to provide (e.g., dispense, apply, etc.) photo resist PR onto the substrate 10 (the photo resist PR may be applied onto the substrate 10 while the substrate 10 is stationary or rotating). The spinning equipment 20 may further include a controller 29 that is communicatively coupled to the drive motor 22 and the dispenser 28 and is configured to control the drive motor 22 and/or the dispenser 28 to control the application and coating of photo resist PR on a substrate 10. The controller 29 may include an electronic device including a memory (e.g., a solid state drive memory) storing a program of instructions and a processor (e.g., a central processing unit (CPU)) configured to execute the program of instructions to implement one or more operations of the spinning equipment 20, including operating the spinning equipment 20 to perform spin-coating of photo resist PR on the substrate 10.

According to some example embodiments, including the example embodiments shown in FIG. 4, the photo resist PR (e.g., photo resist PR moving in the radial direction “r”) may collide with a pad 101 and cause stains on the sensor array 110. For example, the photo resist PR may have an incidental photo resist wave caused by rotation of the substrate 10. In addition, the photo resist PR may have a reflected photo resist wave by colliding with the pad 101. When the incidental photo resist wave and the reflected photo resist wave are combined, the photo resist PR may have a resultant photo resist wave, and thus a filter on the sensor array 110 that is formed based on the photo resist PR may have such a resultant photo resist wave. The resultant photo resist wave (e.g., a resultant photo resist wave in a portion of a photo resist PR that comprises a color filter on the image sensor 100) may have a larger valley and peak than secondary photo resist waves (for example, the incidental photo resist wave and the reflected photo resist wave), and cause stains (e.g., irregular stains) on the sensor array 110, thereby causing images generated by the sensor array 110 to have distortions resulting from such stains (e.g., irregular stains) comprising the photo resist PR (e.g., a color filter formed of the photo resist PR).

According to some example embodiments, including the example embodiments shown in FIG. 5, stains having various shapes and sizes may occur on the sensor array 110 according to a location of the image sensor 100 on the substrate 10. For example, when the image sensor 100 is positioned on the first portion 11 of the substrate 10, the photo resist PR may move in the first flow direction LD1 in the sensor array 110 (e.g., based on the substrate 10 being spin around a central axis 10a of the substrate 10). When the image sensor 100 is positioned on the second portion 12 of the substrate 10, the photo resist PR may move in the second flow direction LD2 in the sensor array 110. In some example embodiments, the first and second flow directions LD1 and LD2 may correspond to a radial direction “r” extending radially from the central axis 10a of the substrate 10. Accordingly, stains corresponding to the flow direction may occur on the sensor array 110. Also, the spacing of the pads 101 may not be constant. Accordingly, the flow rate of the photo resist PR may vary according to the distance between the pads 101, and irregular vortices may occur, resulting in stains of various shapes and sizes on the sensor array 110. Such stains of various shapes and sizes on the sensor array 110 may be referred to herein as “irregular” stains/staining.

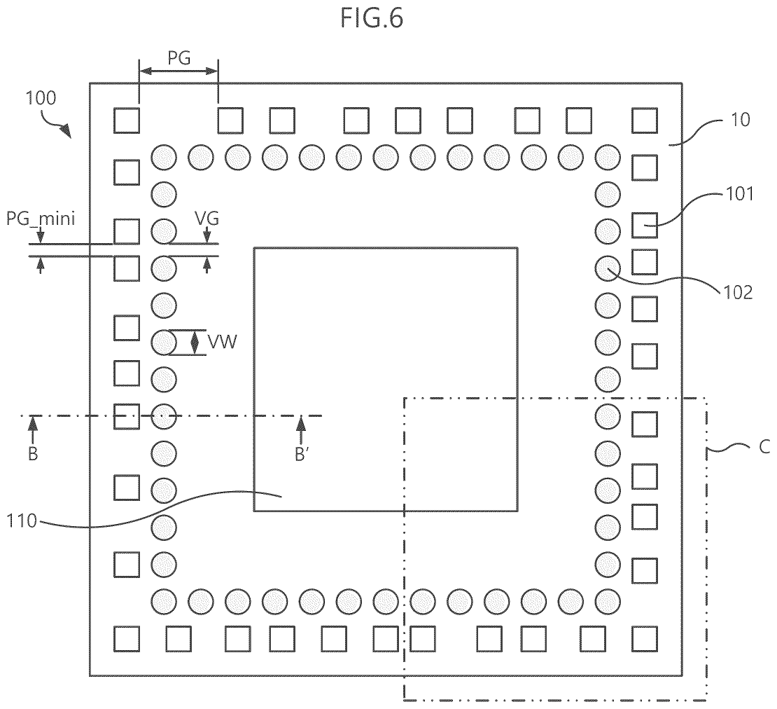

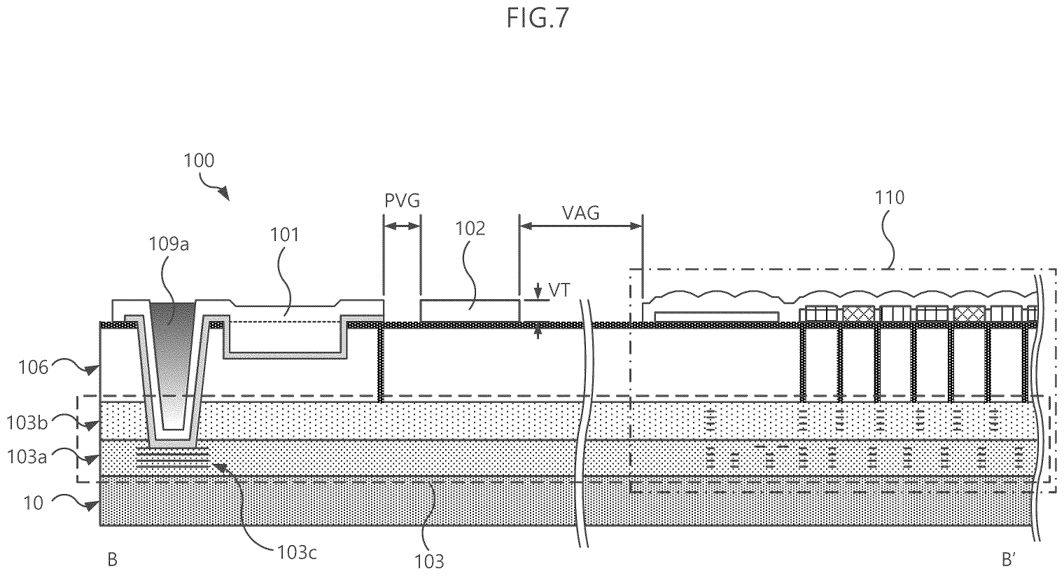

FIG. 6 is a diagram illustrating an image sensor including a vortex generating pattern to reduce, minimize, or prevent staining during photo resist coating according to some example embodiments. FIG. 6 is a top view of the image sensor 100. FIG. 7 is a cross-sectional view illustrating along a line B-B′ of FIG. 6. Referring to FIGS. 6 and 7, the image sensor 100 may include a sensor array 110 disposed at a central portion and pads 101 disposed at a peripheral portion of the sensor array 110. The pads 101 may be connected to the sensor array 110 through internal lines 103 formed inside a substrate 10. The pads 101 may be arranged at irregular intervals for connection with the internal lines 103.

In some example embodiments, the substrate 10 may include a semiconductor substrate, for example a silicon substrate, but example embodiments are not limited thereto. The internal lines 103 may include one or more insulating layers 103a and 103b and conductive lines 103c included therein. The one or more insulating layers 103a and 103b may each independently include an inorganic material, an organic material, an organic/inorganic material, or any combination thereof. The inorganic material may be, for example, silicon oxide, silicon nitride, silicon oxynitride, aluminum oxide, or aluminum nitride, the organic material may be, for example, polyimide, polyamide, polyamideimide, or polyacrylate, and the organic/inorganic material may be, for example, polyorganosiloxane, or polyorganosilazane. The conductive lines 103c may include one or more conductive materials, including for example polysilicon, doped polysilicon, metal (e.g., aluminum (Al)), any combination thereof, or the like. An additional layer 106 may be on the internal lines 103. The additional layer 106 may include an insulation layer including an inorganic material, an organic material, an organic/inorganic material, or any combination thereof as described above. The additional layer 106 may include an organic photoelectric conversion device. In some example embodiments, the sensor array 110 may include a photodiode (e.g., a silicon photodiode integrated in the substrate 10, an organic photoelectric conversion device in the additional layer 106, or the like) that is configured to photoelectrically convert incident light received through one or more color filters of the sensor array 110.

According to some example embodiments, the image sensor 100 may include vortex generating patterns 102. For example, the vortex generating patterns 102 may generate vortices having fine and uniform intervals when a photo resist PR passes between the vortex generating patterns 102. Through the vortex generating patterns 102, the photo resist PR may be coated on the sensor array 110 to include fine and uniform stains. These fine and uniform stains may not affect a performance of the image sensor 100. Accordingly, a defect rate during manufacturing of the image sensor 100 may be reduced, and image sensors 100 may be manufactured to have fewer process defects associated with staining and thus may have improved reliability, an improved image generating performance, or the like based on reduced, minimized, or prevented likelihood of non-uniform staining of the photo resist PR coated on the sensor array 110 of the image sensors 100 in the manufacturing process to manufacture the image sensors 100, based on the image sensors 100 including the plurality of vortex generating patterns 102 as described herein. Each individual one of the vortex generating patterns 102 may be referred to as a vortex generating pattern, a vortex generating structure, or the like. The pads 101 (which in some example embodiments may include a pad electrode) may comprise a conductive material, for example doped polysilicon, a metal (e.g., aluminum), or the like. The vortex generation patterns 102 may include an insulating material, a conductive material, or the like. For example, in some example embodiments the vortex generation patterns 102 may include one or more of silicon oxide, silicon nitride, silicon oxynitride, aluminum oxide, aluminum nitride, polyimide, polyamide, polyamideimide, or polyacrylate, polyorganosiloxane, or polyorganosilazane. In some example embodiments, the vortex generation patterns 102 may include a conductive material that may be the same material comprising the via filling member 109a, including for example doped polysilicon, a metal (e.g., aluminum), or the like and may be formed concurrently as part of a same formation process.

According to some example embodiments, the vortex generating patterns 102 may be disposed between the sensor array 110 and the pads 101. For example, the vortex generating patterns 102 may be arranged to surround the sensor array 110. The smallest distance between one of the pads 101 and one of the vortex generating patterns 102 may be set as a pad-vortex pattern interval PVG. The smallest distance between one of the vortex generating patterns 102 and the sensor array 110 may be set as a vortex pattern-sensor interval VAG. As an example, the pad-vortex pattern interval PVG may be set smaller than the vortex pattern-sensor interval VAG, for example such that the plurality of vortex generating patterns 102 are closer to the pads 101 than to the sensor array 110. As another example, the pad-vortex pattern interval PVG may be set equal to the vortex pattern-sensor interval VAG. As another example, the pad-vortex pattern interval PVG may be set equal to a width VW (e.g., a width in a direction parallel to the substrate 10 of the image sensor 100) of one of the vortex generating patterns 102. As another example, the pad-vortex pattern interval PVG may be set equal to a width VW (e.g., a width in a direction parallel to the substrate 10 of the image sensor 100) of each of the vortex generating patterns 102. As another example, the pad-vortex pattern interval PVG may be set equal to a thickness VT (e.g., a thickness in a direction perpendicular to the substrate 10 of the image sensor 100) of one of the vortex generating patterns 102.

According to some example embodiments, the vortex generating patterns 102 may be arranged at regular intervals (e.g., fixed intervals, constant intervals, etc.) according to a specified interval (for example, vortex pattern interval VG), also referred to as a fixed interval, a constant interval, or the like, such that the vortex pattern intervals VG between adjacent vortex generating patterns 102 of the plurality of vortex generating patterns 102 may each have the same size. The vortex pattern interval VG between the vortex generating patterns 102 (e.g., the vortex pattern interval VG between adjacent vortex generating patterns 102 of the plurality of vortex generating patterns 102) may be set to be smaller than or equal to a pad interval PG between the pads 101 (a pad interval PG between adjacent pads 101 of the plurality of pads 101). As an example, pad intervals PG may have various sizes. The vortex pattern interval VG may be set smaller than an average of the pad intervals PG. As another example, the vortex pattern interval VG may be set equal to the minimum pad interval PG_mini among pad intervals PG (e.g., a smallest pad interval PG among the pad intervals PG of the image sensor 100). As another example, the vortex pattern interval VG may be set smaller than the minimum pad interval PG_mini.

According to some example embodiments, the thickness VT and the width VW of each of the vortex generating patterns 102 may be set in various sizes. As an example, each of the vortex generating patterns 102 may be formed to have a same thickness and a same width as at least one pad 101. As another example, each of the vortex generating patterns 102 may have a thickness or a width smaller than that of one pad 101 (e.g., one particular pad of the plurality of pads 101).

According to some example embodiments, each of the vortex generating patterns 102 may be formed in various shapes. As an example, each of the vortex generating patterns 102 may be formed in a cylindrical shape. As another example, each of the vortex generating patterns 102 may be formed in a polygonal column shape (for example, a triangular column, a quadrangular column, a pentagonal column, or an octagonal column, etc.). As another example, each of the vortex generating patterns 102 may be formed in a cone or polygonal pyramid shape.

As described above, the vortex generating patterns 102 may be arranged at regular intervals between the sensor array 110 and the pads 101, so that when the photo resist PR is coated (e.g., based on the photo resist PR moving over the image sensor 100 at least partially in one or more directions parallel to the substrate 10 so as to move between two or more of the vortex generating patterns 102), the photo resist PR may have fine and uniform vortices. In addition, due to a shape of the vortex generating patterns 102, regardless of a flow direction of the photo resist PR, the fine and uniform vortices of the photo resist PR may be generated during coating of the photo resist PR.

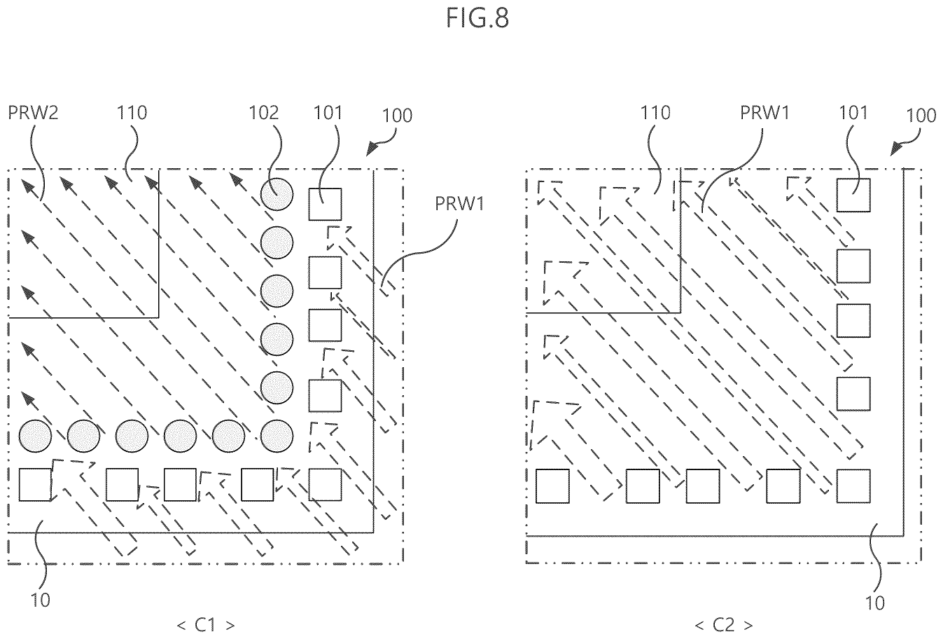

FIG. 8 is a diagram illustrating an effect according to an arrangement of the vortex generating patterns of FIG. 6. FIG. 8 is a view illustrating a part C of FIG. 6 during coating a photo resist PR on the image sensor 100. Referring to FIGS. 6 and 8, the photo resist PR may move from a lower right portion to an upper left portion. In FIG. 8, a size of a dotted line arrow may represent a flow rate of the photo resist PR.

According to some example embodiments, a first case C1 may represent the image sensor 100 including the vortex generating patterns 102. For example, the photo resist PR passed between the pads 101 may generate first vortices PRW1 having first flow rates of various sizes. The first vortices PRW1 having various sizes may be converted into second vortices PRW2 having a fine and uniform second flow rate while passing between the vortex generating patterns 102. Accordingly, the photo resist PR may be uniformly coated on the sensor array 110, thereby reducing, minimizing, or preventing non-uniform or irregular stains (e.g., in color filters formed from the photo resist PR) on the sensor array 110.

According to some example embodiments, a second case C2 may represent the image sensor 100 not including the vortex generating patterns 102 (e.g., not including any vortex generating patterns 102). For example, the photo resist PR passed between the pads 101 may generate the first vortices PRW1 having the first flow rates of the various sizes. The first vortices PRW1 may move to the sensor array 110 as it is. The photo resist PR may be irregularly coated on the sensor array 110 by the first vortices PRW1 having the first flow rates of the various sizes, and irregular stains may be formed on the sensor array 110 (e.g., in color filters formed from the photo resist PR on the sensor array 110).

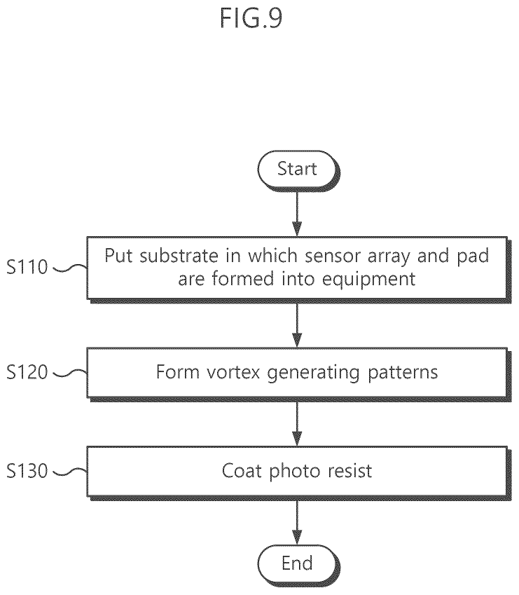

FIG. 9 is a flowchart illustrating an example of a method of manufacturing an image sensor including the vortex generating patterns of FIG. 6. Referring to FIGS. 6, 7, and 9, the vortex generating patterns 102 may be formed between the sensor array 110 and the pads 101 to generate fine and uniform vortices during coating the photo resist PR.

According to some example embodiments, in operation S110, the substrate 10 (for example, a wafer substrate) on which the sensor array 110 and the pads 101 are formed may be put (e.g., input) into an equipment (e.g., a spinning equipment 20). For example, the substrate 10 may include a plurality of image sensors 100. The sensor array 110 may be formed excluding color filters and lens parts.

According to some example embodiments, in operation S120, the vortex generating patterns 102 may be formed in the plurality of image sensors 100. For example, the vortex generating patterns 102 may be disposed between the sensor array 110 and the pads 101. The vortex generating patterns 102 may be arranged to surround the sensor array 110. The vortex generating patterns 102 may be arranged to be surrounded by the pads 101. The vortex generating patterns 102 may be arranged at regular intervals (e.g., fixed intervals) according to a specified interval (for example, the vortex pattern interval VG). As an example, the vortex generating patterns 102 may be formed simultaneously with a via filling member 109a (e.g., in example embodiments where the vortex generating patterns 102 and the via filling member 109a have a same material composition, for example including a conductive material such as aluminum). As another example, after the via filling member 109a is formed, the vortex generating patterns 102 may be formed. The vortex generating patterns 102 may be formed at S120 via one or more various deposition processes, including for example chemical vapor deposition (CVD), physical vapor deposition (PVD), but example embodiments are not limited thereto. The via filling member(s) 109a may be formed via the same or different process as used to form the vortex generating patterns 102, including for example chemical vapor deposition (CVD), physical vapor deposition (PVD), or the like.

According to some example embodiments, the vortex generating patterns 102 may be disposed between the sensor array 110 and the pads 101. For example, the vortex generating patterns 102 may be arranged to surround the sensor array 110. The smallest distance between one of the pads 101 and one of the vortex generating patterns 102 may be set as the pad-vortex pattern interval PVG. The smallest distance between one of the vortex generating patterns 102 and the sensor array 110 may be set as the vortex pattern-sensor interval VAG. As an example, the pad-vortex pattern interval PVG may be set smaller than the vortex pattern-sensor interval VAG. As another example, the pad-vortex pattern interval PVG may be set equal to the vortex pattern-sensor interval VAG. As another example, the pad-vortex pattern interval PVG may be set equal to the width VW of one of the vortex generating patterns 102. As another example, the pad-vortex pattern interval PVG may be set equal to the thickness VT of one of the vortex generating patterns 102.

According to some example embodiments, the vortex generating patterns 102 may be arranged at regular intervals according to a specified interval (for example, the vortex pattern interval VG). The vortex pattern interval VG between the vortex generating patterns 102 may be set to be smaller than or equal to the pad interval PG between the pads 101. As an example, the pad intervals PG may have various sizes. The vortex pattern interval VG may be set smaller than the average of the pad intervals PG. As another example, the vortex pattern interval VG may be set equal to the minimum pad interval PG_mini among the pad intervals PG. As another example, the vortex pattern interval VG may be set smaller than the minimum pad interval PG_mini.

According to some example embodiments, the thickness VT and the width VW of each of the vortex generating patterns 102 may be set in various sizes. The vortex generating patterns 102 may each have a same or substantially same thickness VT and a same or substantially same width VW. As an example, each of the vortex generating patterns 102 may be formed to have the same thickness and width as at least one of the pads 101. As another example, each of the vortex generating patterns 102 may have a thickness or width smaller than that of one of the pads 101 (e.g., smaller than that of each of the pads 101).

According to some example embodiments, each of the vortex generating patterns 102 may be formed in various shapes. As an example, each of the vortex generating patterns 102 may be formed in a cylindrical shape. As another example, each of the vortex generating patterns 102 may be formed in a polygonal column shape (for example, a triangular column, a quadrangular column, a pentagonal column, or an octagonal column, etc.). As another example, each of the vortex generating patterns 102 may be formed in a cone or polygonal pyramid shape.

According to some example embodiments, in operation S130, while the substrate 10 rotates (e.g., around the central axis 10a, based on operation of the spinning equipment 20), the photo resist PR for color filters may be coated on the plurality of image sensors 100. For example, necessary color filters (e.g., RGB color filters) may be formed on the sensor array 110 after the photo resist PR is coated. For example, a photo resist PR including a red-filtering colorant, dye, pigment, or the like may be applied on the substrate 10 and coated on the sensor array 110 based on rotation of the substrate 10 due to operation of the spinning equipment 20, and portions of the photo resist PR may then be removed from portions of the image sensor 100 (e.g., via a dry etching process, a wet etching process, a photo etch process, any combination thereof, or the like) After the color filters are formed, a lens portion may be formed on the sensor array 110. It will be understood that removal of portions of the photo resist PR (e.g., to form color filters), forming of a lens portion, or the like may be performed after removing the substrate 10 from the spinning equipment 20 subsequently to performing the coating of the photo resist PR at S130. In some example embodiments, the vortex generating patterns may be formed at S120 prior to inputting the substrate into the equipment at S110, such that the vortex generating patterns 102 may already be present on the substrate 10.

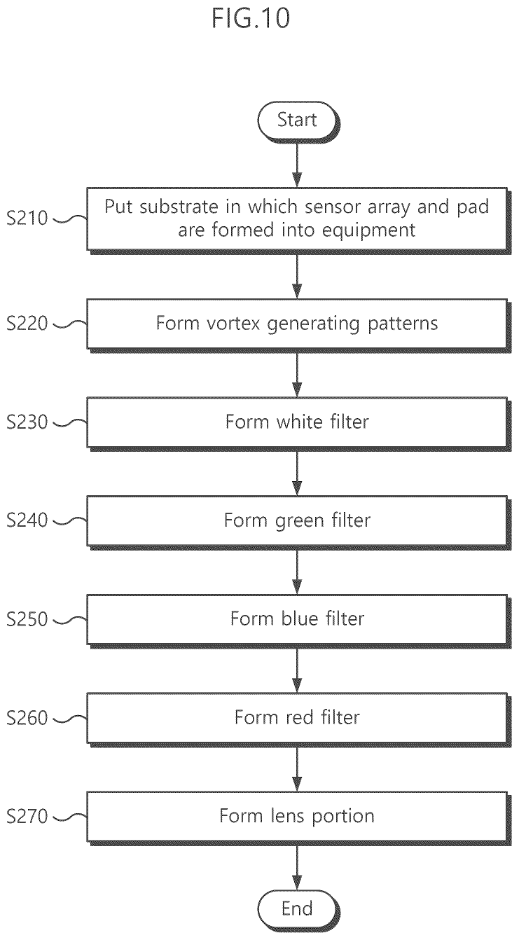

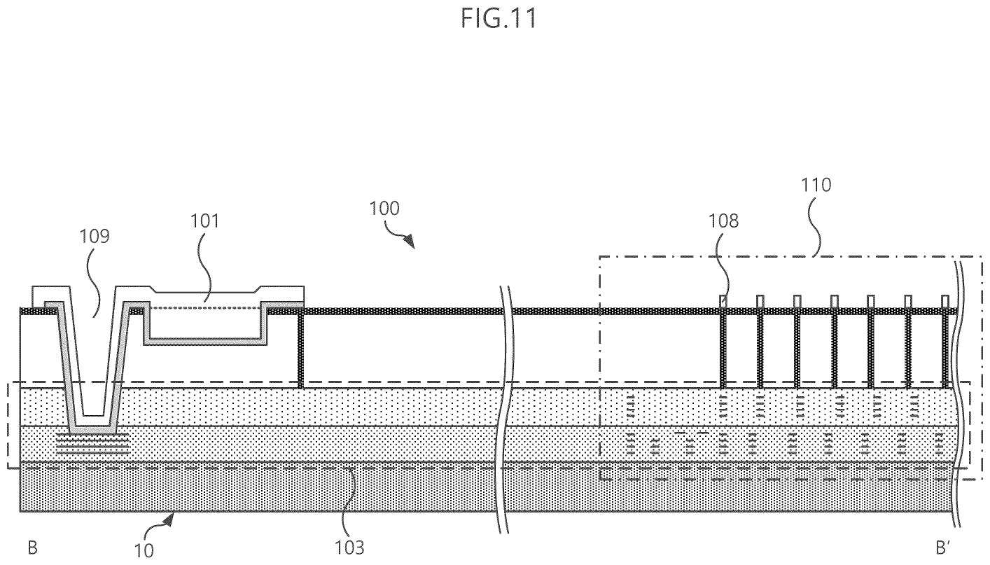

FIG. 10 is a flowchart illustrating another example of a method of manufacturing an image sensor including the vortex generating pattern of FIG. 6. FIGS. 11, 12, 13, 14, 15, 16, and 17 are cross-sectional views illustrating each of steps of manufacturing an image sensor.

According to some example embodiments, in operation S210, the substrate 10 (for example, a wafer substrate) on which the sensor array 110 and the pads 101 are formed may be put (e.g., input) into an equipment (e.g., a spinning equipment 20). For example, the substrate 10 may include a plurality of image sensors 100. The sensor array 110 may be formed excluding color filters and lens parts. Referring to FIG. 11, the image sensor 100 may include the pads 101, a pad via 109, a filter fence 108, the sensor array 110, and lines 103 on the substrate 10. In some example embodiments, the filter fence 108 may include an insulating material as described herein as being included in the insulating layers 103a and 103b, but example embodiments are not limited thereto.

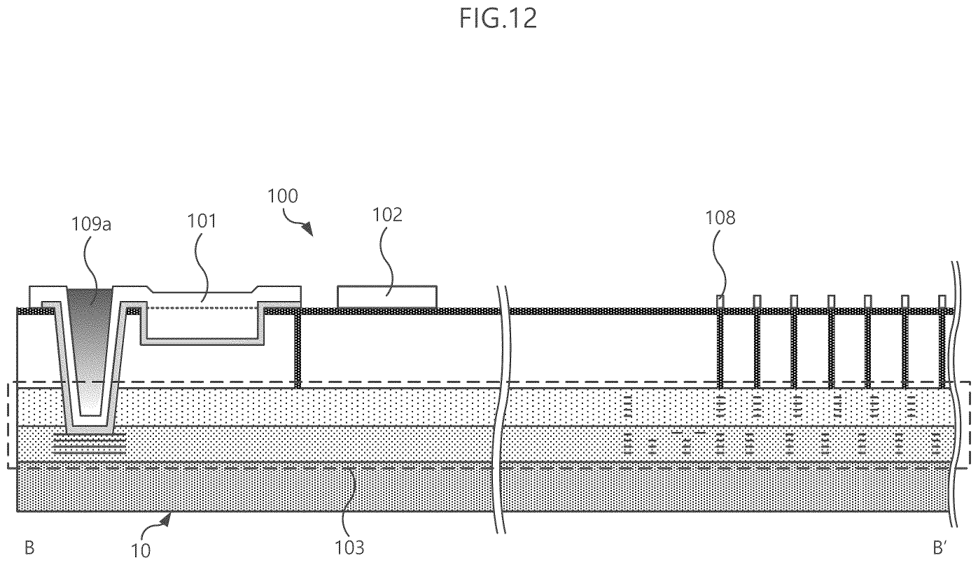

According to some example embodiments, in operation S220, the vortex generating patterns 102 may be formed in the plurality of image sensors 100. For example, the vortex generating patterns 102 may be disposed between the sensor array 110 and the pads 101. The vortex generating patterns 102 may be arranged to surround the sensor array 110. The vortex generating patterns 102 may be arranged at regular intervals according to specified intervals. Referring to FIG. 12, the vortex generating patterns 102 may be formed through the same process as the via filling member 109a. As an example, the vortex generating patterns 102 may be formed simultaneously with the via filling member 109a (e.g., in example embodiments where the vortex generating patterns 102 and the via filling member 109a have a same material composition, for example including a conductive material such as aluminum). As another example, after the via filling member 109a is formed, the vortex generating patterns 102 may be formed. The vortex generating patterns 102 may be formed at S120 via one or more various deposition processes, including for example chemical vapor deposition (CVD), physical vapor deposition (PVD), but example embodiments are not limited thereto. The via filling member(s) 109a may be formed via the same or different process as used to form the vortex generating patterns 102, including for example chemical vapor deposition (CVD), physical vapor deposition (PVD), or the like.

According to some example embodiments, the vortex generating patterns 102 may be disposed between the sensor array 110 and the pads 101. For example, the vortex generating patterns 102 may be arranged to surround the sensor array 110. The vortex generating patterns 102 may be arranged to be surrounded by the pads 101. The smallest distance between one of the pads 101 and one of the vortex generating patterns 102 may be set as a pad-vortex pattern interval PVG. The smallest distance between one of the vortex generating patterns 102 and the sensor array 110 may be set as a vortex pattern-sensor interval VAG. As an example, the pad-vortex pattern interval PVG may be set smaller than the vortex pattern-sensor interval VAG. As another example, the pad-vortex pattern interval PVG may be set equal to the vortex pattern-sensor interval VAG. As another example, the pad-vortex pattern interval PVG may be set equal to a width VW of one of the vortex generating patterns 102. As another example, the pad-vortex pattern interval PVG may be set equal to a thickness VT of one of the vortex generating patterns 102.

According to some example embodiments, the vortex generating patterns 102 may be arranged at regular intervals according to a specified interval (for example, vortex pattern interval VG). The vortex pattern interval VG between the vortex generating patterns 102 may be set to be smaller than or equal to a pad interval PG between the pads 101. As an example, pad intervals PG may have various sizes. The vortex pattern interval VG may be set smaller than an average of the pad interval PG. As another example, the vortex pattern interval VG may be set equal to the minimum pad interval PG_mini among pad intervals PG. As another example, the vortex pattern interval VG may be set smaller than the minimum pad interval PG_mini.

According to some example embodiments, the thickness VT and the width VW of each of the vortex generating patterns 102 may be set in various sizes. The vortex generating patterns 102 may each have a same or substantially same thickness VT and a same or substantially same width VW. As an example, each of the vortex generating patterns 102 may be formed to have a same thickness and a same width as at least one pad 101. As another example, each of the vortex generating patterns 102 may have a thickness or a width smaller than that of one pad 101.

According to some example embodiments, each of the vortex generating patterns 102 may be formed in various shapes. As an example, each of the vortex generating patterns 102 may be formed in a cylindrical shape. As another example, each of the vortex generating patterns 102 may be formed in a polygonal column shape (for example, a triangular column, a quadrangular column, a pentagonal column, or an octagonal column, etc.). As another example, each of the vortex generating patterns 102 may be formed in a cone or polygonal pyramid shape.

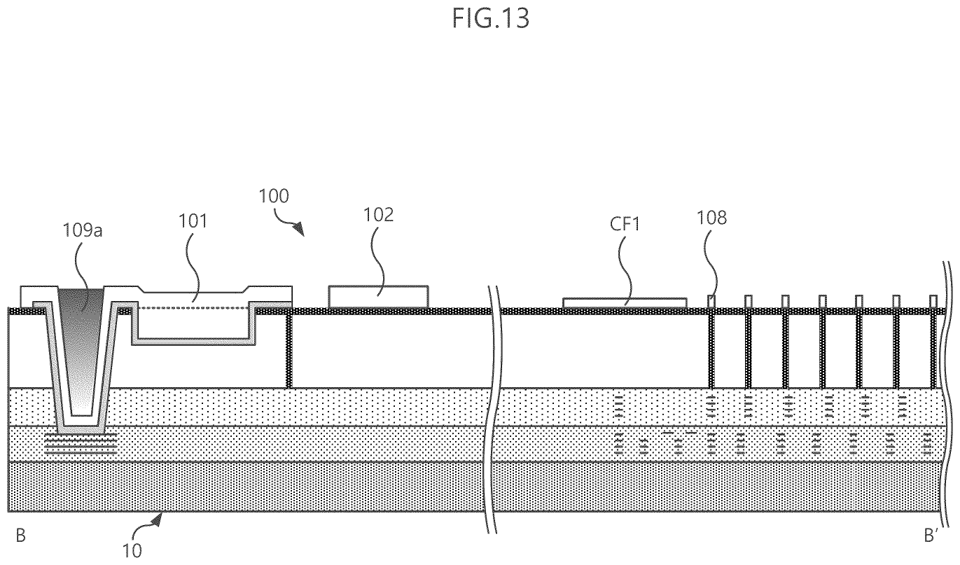

According to some example embodiments, in operation S230, a white filter CF1 may be formed. Referring to FIG. 13, the white filter CF1 may be formed between the vortex generating patterns 102 and the filter fence 108.

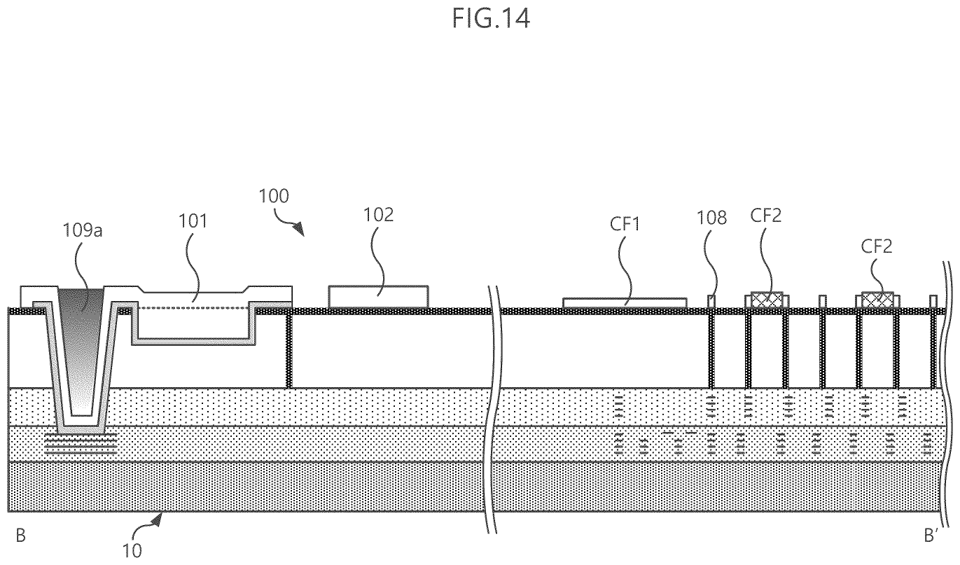

According to some example embodiments, in operation S240, a green filter CF2 may be formed. Referring to FIG. 14, the green filter CF2 may be formed between specified filter fences 108.

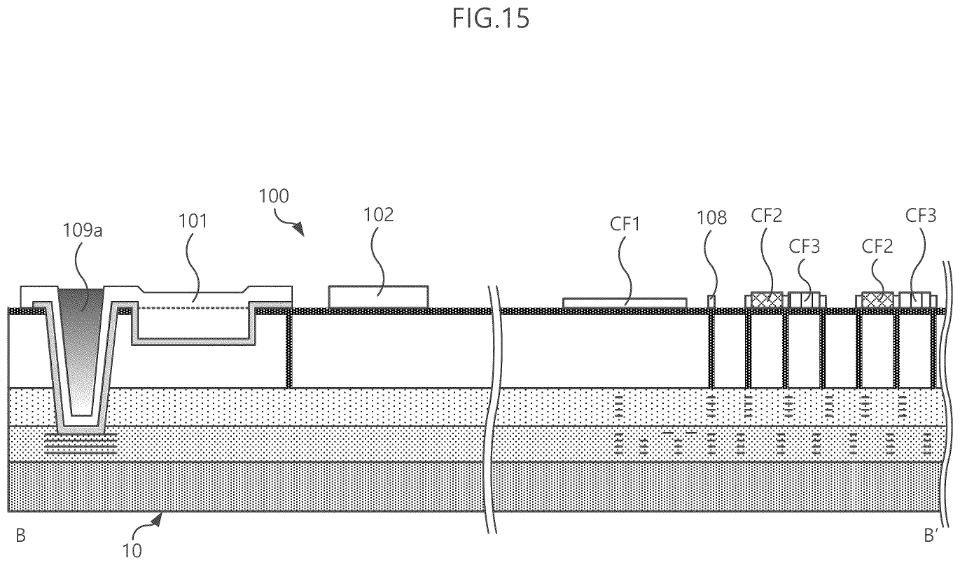

According to some example embodiments, in operation S250, a blue filter CF3 may be formed. Referring to FIG. 15, the blue filter CF3 may be formed between specified filter fences 108. The blue filter CF3 may be disposed adjacent to the green filter CF2.

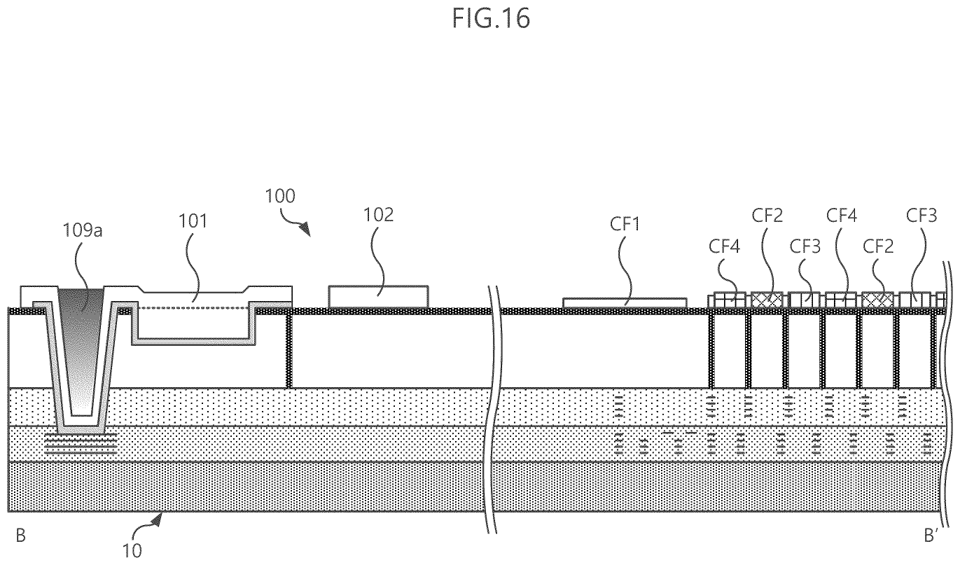

According to some example embodiments, in operation S260, a red filter CF4 may be formed. Referring to FIG. 16, the red filter CF4 may be formed between specified filter fences 108. The red filter CF4 may be disposed adjacent to the green filter CF2. Also, the red filter CF4 may be disposed between the green filter CF2 and the blue filter CF3.

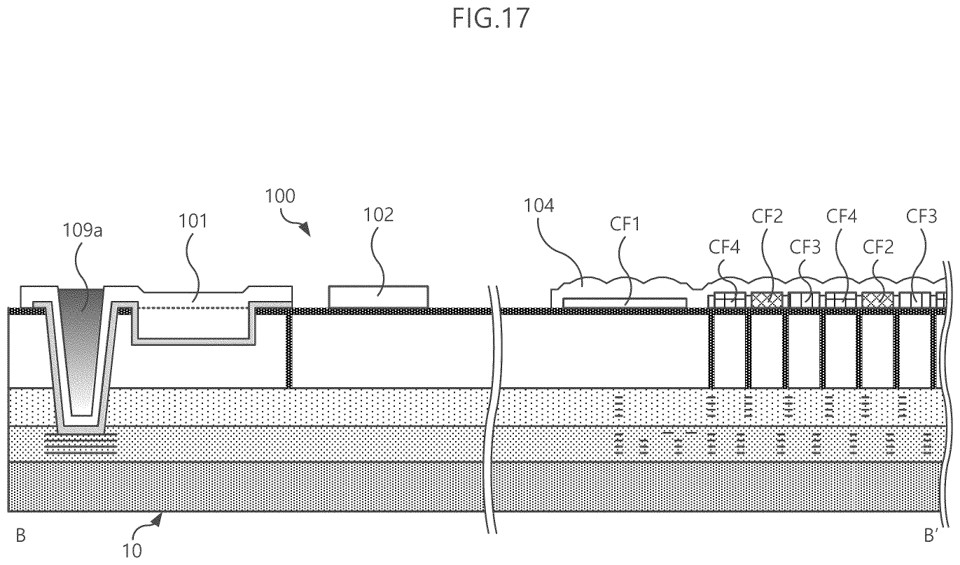

According to some example embodiments, in operation S270, the lens portion 104 may be formed. Referring to FIG. 17, the lens portion 104 may be formed on the white filter CF1, the green filter CF2, the blue filter CF3, and the red filter CF4.

Each of the formations of the white filter CF1, the green filter CF2, the blue filter CF3, and the red filter CF4 at S230 to S260 may include applying a photo resist PR on the substrate 10 and rotating the substrate 10 (e.g., based on operating the spinning equipment 20) so that the photo resist PR coats the image sensors and further covers the sensor arrays 110, wherein in each of operations S230 to S260, the photo resist PR may include a different colorant, dye, pigment, or the like associated with filtering a certain color (or may not include any color dye). For example, the forming of the while filter CF1 at S230 may include applying a photo resist PR that does not include any colorant, dye, pigment, or the like, the forming of the green filter at S240 may include applying a photo resist PR that includes a green colorant, dye, pigment, or the like, the forming of the blue filter at S250 may include applying a photo resist PR that includes a blue colorant, dye, pigment, or the like, and the forming of the red filter at S260 may include applying a photo resist PR that includes a red colorant, dye, pigment, or the like. Each of the formations of the white filter CF1, the green filter CF2, the blue filter CF3, and the red filter CF4 at S230 to S260 may further include, subsequently to coating the respective photo resist PR on the sensor array, removing portions of the respective photo resist PR from portions of the image sensor 100 excluding certain regions (e.g., defined by filter fences 108 as shown in FIGS. 11-17) defining pixel boundaries into which certain color filters are to be located (where such removal may be performed via various removal methods, including for example dry etching, wet etching, photolithography, or the like), so that the remaining respective photo resist PR at the end of the respective operation S230 to S260 is the respective white filter CF1, the green filter CF2, the blue filter CF3, and the red filter CF4 as shown in FIGS. 11 to 16.

The lens portion 104 may include one or more various transparent materials, including for example, SiO₂, Si₃N₄, a resin (e.g., novolac resin), rot the like. The lens portion 104 may be formed on the sensor array 110 via one or more various deposition processes, including for example chemical vapor deposition (CVD), physical vapor deposition (PVD), but example embodiments are not limited thereto.

In some example embodiments, each of operations S220 to S270 are performed while the substrate 10 is in the equipment (e.g., spinning equipment 20), but example embodiments are not limited thereto. For example, in some example embodiments, operation S220 (e.g., forming the vortex generating patterns) may be performed prior to inputting the substrate 10 into the equipment (e.g., based on operation of deposition equipment that is separate from the spinning equipment 20). In some example embodiments, the spinning equipment 20 may include deposition equipment configured to be operated to perform the formation of the vortex generating patterns at S220 while the substrate 10 is inputted in the spinning equipment 20. In some example embodiments, in each of S230 to S260, the application and coating of the respective photo resist PR is performed while the substrate 10 is inputted into the spinning equipment and is performed at least in part based on operating the spinning equipment. In some example embodiments, in each of S230 to S260, the removal of photo resist PR from at least some portions of the image sensor(s) 100 to form the respective color filter of the while filter CF1, the green filter CF2, the blue filter CF3, or the red filter CF4 may include removing the substrate with the coated photo resist PR from the spinning equipment 20 and performing the removal (e.g., via an etching process) using a different equipment (e.g., a photolithography equipment) which may be separate from the spinning equipment. IN some example embodiments, the lens portion formation at S270 may be performed after the substrate 10 is removed from the equipment (e.g., based on operation of deposition equipment that is separate from the spinning equipment 20).

As described above, the vortex generating patterns 102 may be arranged at regular intervals (e.g., a fixed interval between adjacent vortex generating patterns 102 of the vortex generating patterns 102) between the sensor array 110 and the pads 101, so that the photo resist PR may have fine and uniform vortices during coating the photo resist PR. In addition, due to the shape of the vortex generating patterns 102, regardless of the flow direction of the photo resist PR, fine and uniformly vortices of the photo resist PR may be generated during coating the photo resist PR. Accordingly, since the color filters include only fine stains imperceptible to humans, a defect rate of the sensor array 110 may be reduced.

According to the present inventive concepts, stains of color filters in the image sensor may be reduced, minimized, or prevented.

As described herein, any devices, systems, modules, portions, units, controllers, circuits, and/or portions thereof according to any of the example embodiments, and/or any portions thereof (including, without limitation, the image sensor 100, the sensor array 110, the timing generator 120, the row decoder 130, the row driver 140, the CDS 150, the ADC 160, the latch 170, the column decoder 180, the spinning equipment 20, the drive motor 22, the controller 26, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments (e.g., any of the operations in any of the methods shown in FIGS. 9 and 10).

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. A manufacturing method of an image sensor, the manufacturing method comprising:
inputting a substrate in an equipment, wherein a sensor array and a plurality of pads are on the substrate;
forming a plurality of vortex generating patterns at regular intervals between the plurality of pads and the sensor array; and
coating a photo resist while rotating the substrate based on operating the equipment.

2. The manufacturing method of claim 1, wherein the plurality of vortex generating patterns are formed before color filters of the sensor array are formed.

3. The manufacturing method of claim 1, wherein the regular intervals are equal to a minimum interval between adjacent pads of the plurality of pads.

4. The manufacturing method of claim 1, wherein each of the plurality of vortex generating patterns are formed to have a first thickness or a first width that is smaller than or equal to a second thickness or a second width of each of the plurality of pads.

5. The manufacturing method of claim 1, wherein each of the plurality of vortex generating patterns are formed in a cylindrical shape.

6. The manufacturing method of claim 1, wherein a plurality of lines are on the substrate, the plurality of lines connected to the sensor array, and the plurality of vortex generating patterns are formed concurrently with a process of filling a cavity of a vertical via connecting the plurality of pads and the plurality of lines connected to the sensor array.

7. The manufacturing method of claim 1, wherein a distance between one of the plurality of vortex generating patterns and one of the plurality of pads is equal to a width of each of the plurality of vortex generating patterns.

8. The manufacturing method of claim 1, wherein the plurality of vortex generating patterns are disposed closer to the plurality of pads than to the sensor array.

9. The manufacturing method of claim 1, wherein a distance between one of the plurality of vortex generating patterns and one of the plurality of pads is equal to a distance between the one of the plurality of vortex generating patterns and the sensor array.

10. The manufacturing method of claim 1, wherein the coating the photo resist comprises:
forming a first color filter on the sensor array;
forming a second color filter on the sensor array;
forming a third color filter on the sensor array;
forming a fourth color filter on the sensor array; and
and forming a lens portion on the sensor array.

11. A manufacturing method of an image sensor, the manufacturing method comprising:
inputting a substrate in an equipment, wherein a sensor array and a plurality of pads are on the substrate and a plurality of lines are connected to the sensor array on the substrate;
filling a cavity of a vertical via connecting the plurality of pads and the plurality of lines connected to the sensor array;
forming a plurality of vortex generating patterns at regular intervals between the plurality of pads and the sensor array;
coating a photo resist while rotating the substrate based on operating the equipment;
forming color filters on the sensor array; and
forming a lens portion on the sensor array.

12. The manufacturing method of claim 11, wherein the regular intervals are equal to a minimum interval between adjacent pads of the plurality of pads.

13. The manufacturing method of claim 11, wherein a first thickness of each of the plurality of vortex generating patterns is smaller than or equal to a second thickness of each of the plurality of pads.

14. The manufacturing method of claim 11, wherein a first width of each of the plurality of vortex generating patterns is smaller than or equal to a second width of each of the plurality of pads.

15. The manufacturing method of claim 11, wherein a distance between one of the plurality of vortex generating patterns and one of the plurality of pads is equal to a distance between one of the plurality of vortex generating patterns and the sensor array.

16. The manufacturing method of claim 11, wherein a distance between one of the plurality of vortex generating patterns and one of the plurality of pads is smaller than a distance between the one of the plurality of vortex generating patterns and the sensor array.

17. The manufacturing method of claim 11, wherein a distance between one of the plurality of vortex generating patterns and one of the plurality of pads is equal to a thickness of each of the plurality of vortex generating patterns.

18. The manufacturing method of claim 11, wherein a distance between one of the plurality of vortex generating patterns and one of the plurality of pads is equal to a width of each of the plurality of vortex generating patterns.

19. The manufacturing method of claim 11, wherein the forming the color filters comprises:
forming a white filter on the sensor array;
forming a green filter on the sensor array;
forming a blue filter on the sensor array; and
forming a red filter on the sensor array.

20. An image sensor, comprising:
a sensor array including a two-dimensional arrangement of a plurality of unit pixels;
a plurality of pads surrounding the sensor array at irregular intervals; and
a plurality of vortex generating patterns arranged at regular intervals between the plurality of pads and the sensor array,
wherein the regular intervals are equal to a minimum interval of the irregular intervals between the plurality of pads.
